(19) United States
(12) Patent Application Publication
(10) Pub. No.: US 2026/0282458 A1
(43) Pub. Date: Sep. 17, 2026

(54) STRUCTURE FOR HIGH ELECTRON MOBILITY TRANSISTOR WITH P-TYPE III-V SEMICONDUCTOR LAYER IN CHANNEL LAYER

(71) Applicant: GlobalFoundries U.S. Inc., Malta, NY (US)

(72) Inventors: John J. Ellis-Monaghan, Grand Isle, VT (US); Johnatan A. Kantarovsky, South Burlington, VT (US); Ramsey J. Hazbun, Colchester, VT (US); Nathan Smaglik, Essex Junction, VT (US); Rajendran Krishnasamy, Essex Junction, VT (US); Michael J. Zierak, Colchester, VT (US)

(21) Appl. No.: 18/985,722

(22) Filed: Dec. 18, 2024

(51) Int. Cl. H10D 62/10; H10D 30/47; H10D 62/60; H10D 62/824; H10D 64/00

(52) U.S. Cl. CPC H10D 62/102; H10D 30/475; H10D 62/60; H10D 62/824; H10D 64/112

(57) ABSTRACT

A structure for a HEMT and the HEMT are disclosed. The structure may include a first p-type III-V semiconductor layer and a first intrinsic III-V semiconductor channel layer over the first p-type III-V semiconductor layer. A second p-type III-V semiconductor leakage current blocking layer is over the first intrinsic III-V semiconductor channel layer, and a second intrinsic III-V semiconductor channel layer is over the second p-type III-V semiconductor leakage current blocking layer. A III-V semiconductor barrier layer is over the second intrinsic III-V semiconductor channel layer to form a two-dimensional electron gas (2DEG) region at an interface between the two layers. The second p-type III-V semiconductor layer provides a current leakage blocking layer below the 2DEG region. In certain embodiments, the HEMT uses intrinsic gallium nitride for its channel and the current leakage blocking layer includes magnesium gallium nitride.

### STATEMENT REGARDING GOVERNMENT FUNDING

This application was made with government support under contract number HQ0727790700 awarded by the Defense Microelectronics Activity (DMEA). The US government has certain rights in the invention.

### TECHNICAL FIELD

The present disclosure relates to transistors, such as III-V high electron mobility transistors (HEMTs) or III-V metal-insulator-semiconductor HEMTs (MISHEMTs). More particularly, the present disclosure relates to a structure including a p-type III-V semiconductor layer in an n-type III-V semiconductor channel layer for a HEMT.

### BACKGROUND

III-V semiconductor devices, such as high electron mobility transistors (HEMTs) and metal-insulator-semiconductor HEMTs (MISHEMTs), have emerged as a leading technology for radio frequency (RF) and millimeter wave (mmWave) (e.g., 3-300 GHz) wireless applications. HEMTs and MISHEMTs can suffer from current leakage around a gate in a channel layer in an off-state.

### SUMMARY

All aspects, examples and features mentioned below can be combined in any technically possible way.

An aspect of the disclosure provides a high electron mobility transistor (HEMT), comprising: a first intrinsic gallium nitride (GaN) channel layer; a magnesium gallium nitride (Mg—GaN) layer over the first intrinsic GaN channel layer; a second intrinsic GaN channel layer over the Mg—GaN layer; and an aluminum gallium nitride (AlGaN) barrier layer over the second intrinsic GaN channel layer, wherein a two-dimensional electron gas (2 DEG) region is at an interface between the AlGaN barrier layer and the second intrinsic GaN channel layer.

An aspect of the disclosure provides a structure, comprising: a first p-type III-V semiconductor layer; a first intrinsic III-V semiconductor layer over the first p-type III-V semiconductor layer; a second p-type III-V semiconductor layer over the first intrinsic III-V semiconductor layer; a second intrinsic III-V semiconductor layer over the second p-type III-V semiconductor layer; and a III-V semiconductor barrier layer over the second intrinsic III-V semiconductor layer, wherein a two-dimensional electron gas (2DEG) region is at an interface between the III-V semiconductor barrier layer and the second intrinsic III-V semiconductor layer.

An aspect of the disclosure provides a high electron mobility transistor (HEMT), comprising: a semiconductor base layer; a plurality of buffer layers over semiconductor base layer; a first intrinsic gallium nitride (GaN) channel layer over the plurality of buffer layers; a magnesium gallium nitride (Mg—GaN) layer over the first intrinsic GaN channel layer; a second intrinsic GaN channel layer over the Mg—GaN layer; an aluminum gallium nitride (AlGaN) barrier layer over the second intrinsic GaN channel layer, wherein a two-dimensional electron gas (2 DEG) region is at an interface between the AlGaN barrier layer and the second intrinsic GaN channel layer; a gate over the AlGaN barrier layer; a source terminal extending through the AlGaN barrier layer and operatively coupled to second intrinsic GaN channel layer; and a drain terminal extending through the AlGaN barrier layer and operatively coupled to second intrinsic GaN channel layer, wherein the Mg—GaN layer extends under the gate, the source terminal and the drain terminal.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a structure including a high electron mobility transistor (HEMT) according to embodiments of the disclosure;

FIG. 2 shows a cross-sectional view of a structure including a HEMT according to other embodiments of the disclosure; and

FIG. 3 shows a cross-sectional view of a structure including a metal-insulator-semiconductor (MISHEMT) according to additional embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

During formation of an intrinsic III-V semiconductor channel layer for a HEMT or MISHEMT, the layers are unintentionally lightly doped with silicon, making them slightly n-type. It has been discovered that the n-type doping can create a current path from drain to source when the device is turned off, i.e., in an enhancement mode device, with 0 Vgs but a raised voltage (e.g., 10-30V) on the drain terminal. More particularly, while the 2 DEG region is supposed to be depleted when the device is turned off, due to the lightly doped n-type intrinsic III-V semiconductor channel layer, there is a current path therein bypassing the gate, causing drain-source current leakage.

Embodiments of the disclosure include a structure for a high electron mobility transistor (HEMT) or metal-insulator-semiconductor (MISHEMT) and a HEMT or MISHEMT including the structure. The structure may include a first p-type III-V semiconductor layer and a first intrinsic III-V semiconductor channel layer over the first p-type III-V semiconductor layer. A second p-type III-V semiconductor leakage current blocking layer is over the first intrinsic III-V semiconductor channel layer, and a second intrinsic III-V semiconductor channel layer is over the second p-type III-V semiconductor leakage current blocking layer. A III-V semiconductor barrier layer is over the second intrinsic III-V semiconductor channel layer to provide a two-dimensional electron gas (2 DEG) region at an interface between the two layers. The second p-type III-V semiconductor layer provides a current leakage blocking layer below the 2 DEG region. In certain embodiments, the HEMT or MISHEMT uses gallium nitride as its III-V semiconductor material, and magnesium as a p-type dopant for its current leakage blocking layer. In this case, the HEMT or MISHEMT includes a first intrinsic gallium nitride (GaN) channel layer, a magnesium gallium nitride (Mg—GaN) layer over the first intrinsic GaN channel layer, and a second intrinsic GaN channel layer over the Mg—GaN layer. An aluminum gallium nitride (AlGaN) barrier layer is over the second intrinsic GaN channel layer to form the 2 DEG region at an interface between the AlGaN barrier layer and the second intrinsic GaN channel layer. As discussed below, intrinsic GaN material may be unintentionally lightly doped with silicon (an n-type dopant) during processing creating a leakage current path. However, in the disclosed structure the Mg—GaN layer, which is sandwiched between the intrinsic GaN layers, is a p-type doped layer, creating a PNPN junction, that blocks current leakage. In one non-limiting example, at 15 Volts, current leakage may be significantly decreased from e-7 to e-11 microamperes.

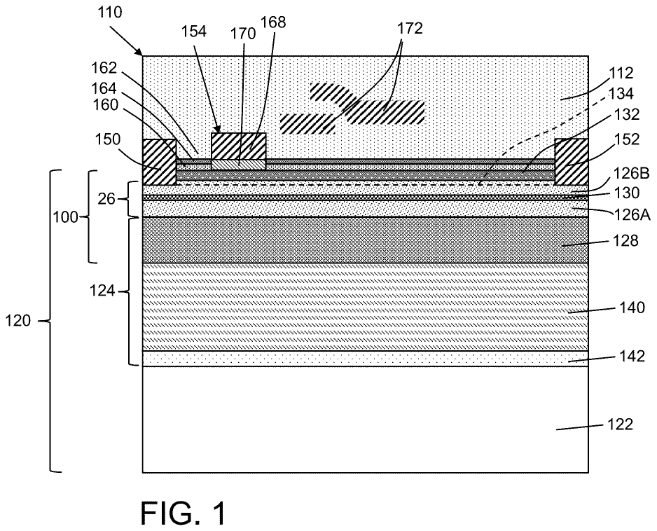

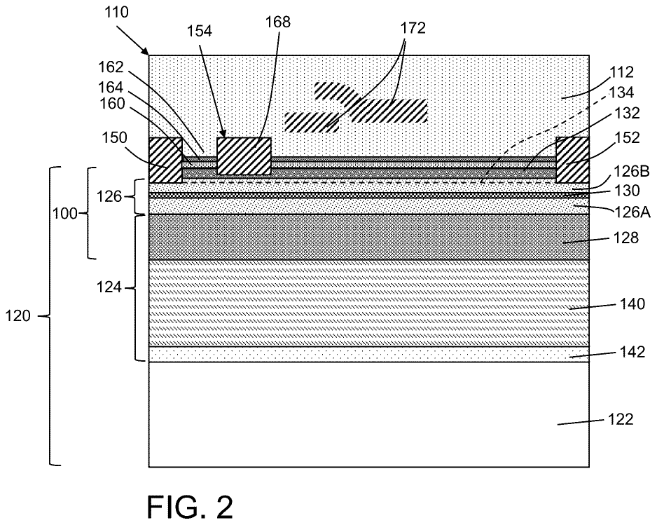

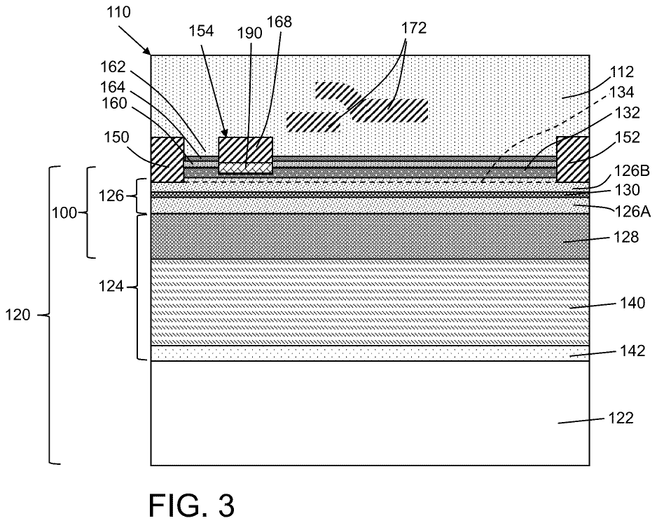

FIG. 1 shows a cross-sectional view of a structure 100, according to embodiments of the disclosure. Structure 100 may include, among other structures, a transistor 110. Transistor 110 may take the form of, for example, a high electron mobility transistor (HEMT) (FIGS. 1-2) or a metal-insulator-semiconductor HEMT (MISHEMT) (FIG. 3). For purposes of description, structure 100 will be described mainly with a HEMT. Transistor 110 (hereafter “HEMT 110” for brevity) in FIG. 1 is illustrated as an enhancement mode HEMT, but as will be described, the teachings of the disclosure are applicable to a depletion mode HEMT (FIG. 2) and to metal-insulator-semiconductor HEMTs (MISHEMTs) (FIG. 3).

Structure 100 and HEMT 110 can include multiple epitaxially grown III-V semiconductor layers of a substrate 120. Those skilled in the art will recognize that a III-V semiconductor refers to a compound obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP).

Generally, substrate 120 may include a semiconductor base 122, a plurality of buffer layers 124 over semiconductor base 122, a channel layer 126 over buffer layers 124, and a barrier layer 132 on channel layer 126. More particularly, structure 100 within substrate 120 may include a first p-type III-V semiconductor layer 128 (i.e., uppermost layer of buffer layers 124) and a first intrinsic III-V semiconductor layer 126A over first p-type III-V semiconductor layer 128. As will be described further, first intrinsic III-V semiconductor layer 126A provides a first part of channel layer 126. Structure 100 also includes a second p-type III-V semiconductor layer 130 over first intrinsic III-V semiconductor layer 126A. As will be described further, second p-type III-V semiconductor layer 130 provides a current leakage blocking layer within channel layer 126. Structure 100 also includes a second intrinsic III-V semiconductor layer 126B over second p-type III-V semiconductor layer 130 that provides a second part of channel layer 126. Structure 100 also includes a III-V semiconductor barrier layer 132 over second intrinsic III-V semiconductor layer 126B. A two-dimensional electron gas (2 DEG) region 134 is at an interface between III-V semiconductor barrier layer 132 and second intrinsic III-V semiconductor layer 126B.

With further regard to the specific layers of structure 100, semiconductor base 122 can be, for example, a silicon or silicon-based substrate (e.g., a silicon carbide (SiC) substrate), a sapphire substrate, a III-V semiconductor substrate (e.g., a gallium nitride (GaN) substrate or some other suitable III-V semiconductor substrate), a silicon substrate (perhaps doped p-type), or any other suitable substrate for a III-V semiconductor device.

Buffer layers 124 can be employed to facilitate growth of channel layer 126 and to provide for lattice constants of substrate 120 below and channel layer 126 above. First p-type III-V semiconductor layer 128 is an uppermost layer of plurality of buffer layers 124. Buffer layers 124 may include a plurality of (additional) layers including, for example, a plurality of carbon-doped III-V semiconductor layers 140 under first p-type III-V semiconductor layer 128, a nucleation layer 142 under plurality of carbon-doped III-V semiconductor buffer layers 142. Semiconductor base layer 122 is under nucleation layer 142. Buffer layer(s) 124 can be doped or undoped. For example, uppermost buffer layer 128 of buffer layers 124 may include gallium nitride and a first p-type dopant. Hence, first p-type III-V semiconductor layer 128 is referenced hereafter as “pGaN layer 128”. In certain embodiments, pGaN layer 128 can include a carbon dopant, i.e., it is a carbon-doped gallium nitride (C-GaN) or it may include any other material suitable for use as a buffer layer of a HEMT or MISHEMT. Optionally, as noted, other buffer layer(s) 140 can also be carbon-doped gallium nitride, perhaps at different concentrations.

Channel layer 126, including first and second intrinsic III-V semiconductor layers 126A, 126B, may also include gallium nitride. Alternatively, first and second intrinsic III-V semiconductor layers 126A, 126B (hereafter “channel layers” or “intrinsic GaN channel layers” 126A, 126B for brevity) can be made of any other III-V semiconductor compound suitable for use as a channel layer in a HEMT or MISHEMT. During epitaxial formation of channel layers 126A, 126B, they are unintentionally lightly doped with silicon, making them slightly n-type. As noted, the n-type doping can create a current path from drain to source when HEMT 110 is turned off, i.e., with 0 Vgs but a raised voltage (e.g., 10-30V) on the drain terminal. More particularly, while 2 DEG region 134 is supposed to be depleted when HEMT 110 is turned off, due to the lightly doped n-type, intrinsic GaN channel layer 126, there is a current path therein bypassing a gate 154 of HEMT 110, causing drain-source current leakage. In order to address this situation, second p-type III-V semiconductor layer 130 is provided between channel layers 126A, 126B to provide a current blocking layer. Second p-type III-V semiconductor layer 130 can include gallium nitride and a second p-type dopant different than the first p-type dopant of pGaN layer 128 of buffer layers 124. In certain embodiments, the second p-type dopant may include magnesium to form a Mg—GaN layer. Hence, the first p-type dopant of uppermost buffer layer 182 may include carbon dopant, and the second p-type dopant of second p-type III-V semiconductor layer 130 may include magnesium dopant. Hereafter, second p-type III-V semiconductor layer 130 may be referenced as “Mg—GaN layer 130” for brevity. Mg—GaN layer 130 is a relatively thin layer compared to channel layer 126A. For example, Mg—GaN layer 130 may have a thickness in a range of 5 to 40 nanometers, channel layer 126B may have a thickness in a range of 5 to 40 nanometers, and channel layer 126A may have a thickness in a range of 20 to 100 nanometers. Channel layers 126A, 126B do not necessarily have the same thickness. Channel layer 126A may be thicker than Mg—GaN layer 130.

III-V semiconductor barrier layer 132 can have a band gap that is wider than the bandgap of channel layer 126 for the device channel. In certain embodiments, barrier layer 132 can be an aluminum gallium nitride (AlGaN) barrier layer or a barrier layer of any other material suitable for use as a barrier layer in a HEMT or MISHEMT. Those skilled in the art will recognize that III-V semiconductor barrier layer 132 (hereafter “barrier layer 132” or “AlGaN barrier layer” for brevity) and channel layer 126 materials can be selected so that a heterojunction is formed at the interface between the two layers, thereby resulting in the formation of 2DEG region 134 in channel layer 126 (see dashed box). This 2 DEG region 134 in channel layer 126, and more particularly, second channel layer 126B, can provide the conductive pathway for the drifting of charges between a source terminal 150 and a drain terminal 152 of HEMT 110. As will be described further herein, a gate 154 of transistor is over barrier layer 132 to control operation of 2 DEG region 134 in channel layer 126. HEMT 110 may be, as shown in FIG. 2, a depletion mode HEMT or, as shown in FIGS. 1 and 3, respectively, an enhancement mode HEMT or an enhancement mode MISHEMT.

For purposes of illustration, the figures and the description depict the epitaxially grown layers (e.g., certain layers of buffer layers 124; channel layer 126 (including layers 126A, 126B); Mg—GaN layer 130; and uppermost buffer layer 128) as being single layered structures (i.e., comprising one layer of buffer material, one layer of channel material and one layer of barrier material). However, it should be understood that, alternatively, any one or more of the epitaxially grown layers could be multi-layered structures (e.g., comprising multiple sub-layers of different buffer materials, multiple sub-layers of different III-V semiconductor channel materials and/or multiple sub-layers of different barrier materials). The various dopants described herein may be added during the epitaxial growth process of the layers.

One or more passivation layers may be over barrier layer 132. In the example shown, two passivation layers 160, 162 are shown with an etch stop layer 164 therebetween. Passivation layers 160, 162 may include one or more layers of any appropriate passivation material such as but not limited to aluminum oxide, silicon nitride and/or silicon oxide. For purposes of illustration, the figures and the description depict passivation layers 160, 162 as being single layered structures. However, it should be understood that, alternatively, one or both passivation layers 160, 162 could be multi-layered structures, e.g., comprising multiple sub-layers of different passivation materials. In certain embodiments, passivation layer 162 may include any interlevel or intralevel dielectric material including inorganic dielectric materials, organic dielectric materials, or combinations thereof. In this case, suitable passivation layer 162 (also referred to herein as “dielectric layer”) materials may include but are not limited to: silicon oxide; silicon nitride; carbon-doped silicon dioxide materials; fluorinated silicate glass (FSG); organic polymeric thermoset materials; silicon oxycarbide; SiCOH dielectrics; fluorine doped silicon oxide; spin-on glasses; silsesquioxanes, including hydrogen silsesquioxane (HSQ), methyl silsesquioxane (MSQ) and mixtures or copolymers of HSQ and MSQ; benzocyclobutene (BCB)-based polymer dielectrics, and any silicon-containing low-k dielectric.

Etch stop layer 164 may be provided between passivation layers 160, 162 to protect the lower passivation layer 160 during etching processes. Etch stop layer 164 may include any now known or later developed etch stop material such as silicon nitride. Passivation layers 160, 162 and etch stop layer 164 may be formed using any appropriate deposition technique, e.g., chemical vapor deposition.

Structure 100 includes a gate 154 over barrier layer 132. Gate 154 extends through passivation (dielectric) layers 160, 162 and etch stop layer 164 to barrier layer 132. Structure 100 may also include a source terminal 150 laterally to a first side (left as shown in FIG. 1) of gate 154, and a drain terminal 152 laterally to a second, opposing side (right as shown in FIG. 1) of gate 154. Source terminal 150 extends through barrier layer 132 and is operatively coupled to second intrinsic III-V semiconductor layer 126B; and drain terminal 152 extends through barrier layer 132 and is operatively coupled to second intrinsic III-V semiconductor layer 126B. As used in this context, “operatively coupled” indicates source terminal 150 and drain terminal 152 contact or are close enough to second intrinsic III-V semiconductor layer 126B for the device to operate. Mg—GaN layer 130 extends under gate 154, source terminal 150 and drain terminal 152.

Structure 100 may also optionally include a field plate 172 positioned laterally to a side (e.g., right side in FIGS. 1-3)) of gate 154. In FIGS. 1-2, field plate 172 is between gate 154 and drain terminal 152; however, it can alternatively be between gate 154 and source terminal 150. Although shown as a split field plate 172, it can take any now know or later developed form of field plate 172.

In certain embodiments, as shown in FIG. 1, gate 154 may include a plurality of layers including, for example, a gate conductor layer 168 and an optional p-type GaN (pGaN) gate layer 170 (as illustrated) stacked vertically between barrier layer 132 and gate conductor layer 168. With the inclusion of optional pGaN gate layer 170, gate 154 may also be referenced herein as a “pGaN gate.” pGaN gate layer 170 may include the same dopant as pGaN layer 128, but pGaN gate layer 170 of gate 154 has a higher p-type dopant concentration than pGaN layer 128, i.e., second p-type III-V semiconductor layer. Those skilled in the art will recognize that with pGaN gate layer 170 in gate 154, HEMT 110 functions as an enhancement mode (e-mode) device. Without pGaN gate layer 170 in gate 154, as shown in FIG. 2, HEMT 110 functions as a depletion mode (d-mode) device. “Enhancement mode” indicates HEMT 110 is typically in an off-state and requires a positive voltage (referred to as a “threshold voltage”) to be applied to gate 154 to turn it on, i.e., enhance/allow electron flow through 2 DEG region 134 and channel layer 126. “Depletion mode” indicates HEMT 110 is typically in an on-state and requires a negative voltage (referred to as a “pinch-off voltage”) to be applied to gate 154 to turn it off, i.e., to deplete electron flow through 2 DEG region 134 in channel layer 126. In certain embodiments, pGaN gate layer 170 is in direct contact with gate conductor layer 168, i.e., there are no intervening layers. Gate conductor layer 168 may include, for example, a metal or metal alloy appropriate for forming a Schottky contact gate terminal such as but not limited to gold, titanium, nickel-gold or titanium-platinum-gold. Alternatively, gate conductor layer 168 may include polysilicon. pGaN gate layer 170 may include, for example, p-type doped gallium nitride or any other suitable p-type doped III-V semiconductor material. The p-type dopant may include any appropriate p-type dopant for the III-V semiconductor material used, e.g., for GaN such as but not limited to magnesium, zinc, cadmium and carbon. In certain embodiments, pGaN gate layer 170 is doped with magnesium. As noted, gate 154 is in electric contact with barrier layer 132 so it can control functioning of 2 DEG region 134. Source terminal 150 and drain terminal 152 may each include an ohmic metal or metal alloy such as but not limited to titanium aluminum or titanium nitride, to provide ohmic contacts to channel layer 126B. Field plate 172 may also include the same ohmic metal or metal alloy.

Certain embodiments of the disclosure also include a HEMT 110. HEMT 110 may include first intrinsic GaN channel layer 126A, and Mg—GaN layer 130 over first intrinsic GaN channel layer 126A. The HEMT may also include second intrinsic GaN channel layer 126B over Mg—GaN layer 130, and AlGaN barrier layer 132 over second intrinsic GaN channel layer 126B. 2 DEG region 134 is at an interface between AlGaN barrier layer 132 and second intrinsic GaN channel layer 126B. HEMT 110 may further include gate 154, e.g., a pGaN gate, over AlGaN barrier layer 132, source terminal 150 extending through AlGaN barrier layer 132 to second intrinsic GaN channel layer 126B, and drain terminal 152 extending through AlGaN barrier layer 132 to second intrinsic GaN channel layer 126B. As shown in FIG. 1, with pGaN gate layer 170 in gate 154 (forming a pGaN gate), HEMT 110 is an enhancement mode HEMT, and without pGaN gate layer 170, as shown in FIG. 2, HEMT 110 is a depletion mode HEMT. As noted, Mg—GaN layer 130 extends under gate 154, source terminal 150 and drain terminal 152. pGaN layer 128, which is part of buffer layers 124, may be under first intrinsic GaN channel layer 126A. As noted, where pGaN gate layer 170 is used for gate 154, it has a higher p-type dopant concentration than pGaN layer 128, e.g., 4-15 times higher. In certain embodiments, pGaN layer 128 includes a carbon dopant, and gate 154, i.e., pGaN gate layer 170, includes a magnesium dopant. As noted, Mg—GaN layer 130 is a relatively thin layer compared to channel layer 126A, e.g., it may have a thickness in a range of 5 to 40 nanometers while channel layer 126A has a thickness in a range of 20 to 100 nanometers. In certain embodiments, Mg—GaN layer 130 is thinner than channel layer 126A therebelow.

In additional embodiments, HEMT 110 may include semiconductor base layer 122, nucleation layer 142 over semiconductor base layer 122, and plurality of (additional) buffer layers 140 over semiconductor base layer 122. In addition, HEMT 110 may include first intrinsic GaN channel layer 126A over buffer layers 124, Mg—GaN layer 130 over first intrinsic GaN channel layer 126A, and second intrinsic GaN channel layer 126B over Mg—GaN layer 130. HEMT 110 may also include AlGaN barrier layer 132 over second intrinsic GaN channel layer 126B. As noted, 2 DEG region 134 is at an interface between AlGaN barrier layer 132 and second intrinsic GaN channel layer 126B. Gate 154 is over AlGaN barrier layer 132. Source terminal 150 extend through AlGaN barrier layer 132 to second intrinsic GaN channel layer 126B, and drain terminal 152 may extend through AlGaN barrier layer 132 to second intrinsic GaN channel layer 126B. Mg—GaN layer 130 extends under gate 154, source terminal 150 and drain terminal 152, i.e., to create a current leakage blocking layer. As noted, Mg—GaN layer 130 is a relatively thin layer compared to channel layer 126A, e.g., it may have a thickness in a range of 5 to 40 nanometers while channel layer 126A has a thickness in a range of 20 to 100 nanometers. In certain embodiments, Mg—GaN layer 130 is thinner than channel layer 126A therebelow. Buffer layers 124 includes uppermost pGaN layer 128 and, as shown in FIG. 1, gate 154 may include pGaN gate layer 170. Where pGaN gate layer 170 is used, it has a higher p-type dopant concentration than uppermost pGaN layer 128. In addition, pGaN layer 128 may include a different dopant than pGaN gate layer 170, e.g., carbon and magnesium, respectively.

FIG. 3 shows a cross-sectional view of structure 100 in the form of a HEMT 110 in the form of a MISHEMT, e.g., an enhancement mode MISHEMT. MISHEMT 110 is identical to the HEMT version 110 described herein relative to FIG. 2, except gate 154 includes an additional gate dielectric layer 190 between gate conductor layer 168 (e.g., metal or polysilicon) and 2 DEG region 134, forming a metal-insulator-semiconductor (MIS) interface. Although not shown, gate dielectric layer 190 can also line the gate opening and, optionally, can extend laterally onto the dielectric surface at the top edge of the gate opening. Gate dielectric layer 190 can be a dielectric material with a relatively high dielectric constant (K) (e.g., K is greater than the 3.9 dielectric constant of silicon dioxide). This high-K dielectric material could be, for example, aluminum oxide, tantalum oxide, zirconium oxide, a hafnium (Hf)-based dielectric material (e.g., hafnium oxide, hafnium silicon oxide, hafnium silicon oxynitride, hafnium aluminum oxide, etc.) or some other suitable high-K dielectric material. Alternatively, gate dielectric layer 190 could be, for example, a silicon dioxide layer or a layer of any other dielectric material suitable for use as a gate dielectric layer of a MISHEMT. Gate conductor layer 168 can fill the remaining space within the gate opening.

Embodiments of the disclosure provide various technical and commercial advantages, examples of which are discussed herein. As noted, the Mg—GaN layer creates a p-type doped layer, creating a PNPN junction, that blocks current leakage with minimal impact on other operational parameters. In one non-limiting example, at 15 Volts, current leakage may be significantly decrease from e-7 to e-11 microamperes.

The structure and method as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A high electron mobility transistor (HEMT), comprising:
a first intrinsic gallium nitride (GaN) channel layer;
a magnesium gallium nitride (Mg—GaN) layer over the first intrinsic GaN channel layer;
a second intrinsic GaN channel layer over the Mg—GaN layer; and
an aluminum gallium nitride (AlGaN) barrier layer over the second intrinsic GaN channel layer,
wherein a two-dimensional electron gas (2 DEG) region is at an interface between the AlGaN barrier layer and the second intrinsic GaN channel layer.

2. The HEMT of claim 1, further comprising:
a p-type gallium nitride (pGaN) gate over the AlGaN barrier layer;
a source terminal extending through the AlGaN barrier layer and operatively coupled to the second intrinsic GaN channel layer; and
a drain terminal extending through the AlGaN barrier layer and operatively coupled to the second intrinsic GaN channel layer,
wherein the Mg—GaN layer extends under the pGaN gate, the source terminal and the drain terminal.

3. The HEMT of claim 2, further comprising a p-type gallium nitride (pGaN) layer under the first intrinsic GaN channel layer.

4. The HEMT of claim 3, wherein the pGaN gate has a higher p-type dopant concentration than the pGaN layer.

5. The HEMT of claim 3, wherein the pGaN layer includes a carbon dopant, and the pGaN gate includes a magnesium dopant.

6. The HEMT of claim 3, further comprising a plurality of buffer layers under the pGaN layer, a nucleation layer under the plurality of buffer layers, and a semiconductor base layer under the nucleation layer.

7. The HEMT of claim 1, wherein the Mg—GaN layer has a thickness in a range of 5 to 40 nanometers.

8. The HEMT of claim 7, wherein the first GaN channel layer has a thickness in a range of 20 to 100 nanometers and is thicker than the Mg—GaN layer.

9. A structure, comprising:
a first p-type III-V semiconductor layer;
a first intrinsic III-V semiconductor layer over the first p-type III-V semiconductor layer;
a second p-type III-V semiconductor layer over the first intrinsic III-V semiconductor layer;
a second intrinsic III-V semiconductor layer over the second p-type III-V semiconductor layer; and
a III-V semiconductor barrier layer over the second intrinsic III-V semiconductor layer,
wherein a two-dimensional electron gas (2 DEG) region is at an interface between the III-V semiconductor barrier layer and the second intrinsic III-V semiconductor layer.

10. The structure of claim 9, wherein:
the first p-type III-V semiconductor layer includes gallium nitride and a first p-type dopant;
the first and second intrinsic III-V semiconductor layers include gallium nitride;
the second p-type III-V semiconductor layer includes gallium nitride and a second p-type dopant different than the first p-type dopant; and
the III-V semiconductor barrier layer includes aluminum gallium nitride.

11. The structure of claim 10, wherein the first p-type dopant includes carbon, the second p-type dopant includes magnesium.

12. The structure of claim 9, further comprising:
a p-type gallium nitride (pGaN) gate over the III-V semiconductor barrier layer;
a source terminal extending through the III-V semiconductor barrier layer and operatively coupled to second intrinsic III-V semiconductor layer; and
a drain terminal extending through the III-V semiconductor barrier layer and operatively coupled to second intrinsic III-V semiconductor layer,
wherein the structure includes a high electron mobility transistor (HEMT), and
wherein the second p-type III-V semiconductor layer extends under the pGaN gate, the source terminal and the drain terminal.

13. The structure of claim 12, wherein the pGaN gate has a higher p-type dopant concentration than the second p-type III-V semiconductor layer.

14. The structure of claim 9, wherein the second p-type III-V semiconductor layer has a thickness in a range of 5 to 40 nanometers.

15. The structure of claim 14, wherein the first intrinsic III-V semiconductor layer has a thickness in a range of 20 to 100 nanometers and is thicker than the Mg—GaN layer.

16. The structure of claim 9, wherein the first p-type III-V semiconductor layer is part of a plurality of buffer layers further including a plurality of carbon-doped III-V semiconductor layers under the first p-type III-V semiconductor layer, a nucleation layer under the plurality of carbon-doped III-V semiconductor buffer layers, and a semiconductor base layer under the nucleation layer.

17. A high electron mobility transistor (HEMT), comprising:
a semiconductor base layer;
a plurality of buffer layers over semiconductor base layer;
a first intrinsic gallium nitride (GaN) channel layer over the plurality of buffer layers;
a magnesium gallium nitride (Mg—GaN) layer over the first intrinsic GaN channel layer;
a second intrinsic GaN channel layer over the Mg—GaN layer;
an aluminum gallium nitride (AlGaN) barrier layer over the second intrinsic GaN channel layer, wherein a two-dimensional electron gas (2 DEG) region is at an interface between the AlGaN barrier layer and the second intrinsic GaN channel layer;
a gate over the AlGaN barrier layer;
a source terminal extending through the AlGaN barrier layer and operatively coupled to second intrinsic GaN channel layer; and
a drain terminal extending through the AlGaN barrier layer and operatively coupled to second intrinsic GaN channel layer,
wherein the Mg—GaN layer extends under the gate, the source terminal and the drain terminal.

18. The HEMT of claim 17, wherein the plurality of buffer layers includes an uppermost p-type gallium nitride (pGaN) layer and the gate includes a p-type gallium nitride (pGaN) gate layer, wherein the pGaN gate layer has a higher p-type dopant concentration than the uppermost pGaN layer.

19. The HEMT of claim 18, wherein the uppermost pGaN layer includes a carbon dopant, and the pGaN gate layer includes a magnesium dopant.

20. The HEMT of claim 17, wherein the Mg—GaN layer and the second intrinsic GaN layer each have a thickness in a range of 5 to 40 nanometers, and the first intrinsic GaN channel layer has a thickness in a range of 20 to 100 nanometers and is thicker than the Mg—GaN layer.
